(19) United States
(12) Patent Application Publication
(10) Pub. No.: US 2016/0295720 A1
(43) Pub. Date: Oct. 6, 2016

(54) ELECTRONIC MODULE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: CHING-JOU CHEN, New Taipei (TW); WEN-HSIANG HUNG, New Taipei (TW); CHUN-BAO GU, Wuhan (CN); HONG-MEI ZHANG, Wuhan (CN)

(21) Appl. No.: 14/691,205

(22) Filed: Apr. 20, 2015

(30) Foreign Application Priority Data
Apr. 2, 2015 (CN) 201510152457.9

(51) Int. Cl. H05K 5/02

(52) U.S. Cl. CPC H05K 5/0217; H05K 5/0247

(57) ABSTRACT

An electronic module includes a case and a connecting member. The case includes a top panel and a side panel coupled to the top panel and substantially perpendicular to the top panel. The top panel includes two opposite elastic pieces. The connecting member includes a cable extending from the side panel and a connector coupled to the cable. The connector is attached to the top panel, and the two opposite elastic pieces are deformable to engage with the connector to prevent the connector from disengaging from the top panel.

### FIELD

The subject matter herein generally relates to an electronic module used in an electronic device, such as a computer.

### BACKGROUND

An electronic device, such as a computer, is commonly assembled by a mechanical arm. The electronic device can include an enclosure and a plurality of electronic modules received in the enclosure. The plurality of electronic modules can include a power supply module, a motherboard, a fan, a storage device, and such. Each electronic module can be connected to another electronic module via a cable connector.

### BRIEF DESCRIPTION OF THE DRAWINGS

Implementations of the present technology will now be described, by way of example only, with reference to the attached figures.

FIG. 1 is an isometric view of an embodiment of an electronic module.

FIG. 2 is an enlarged view of a circled portion II of the electronic module of FIG. 1.

FIG. 3 is an assembled view of the electronic module of FIG. 1.

FIG. 4 is similar to FIG. 3, but viewed from a different angle.

FIG. 5 is an enlarged view of a circled portion V of the electronic module of FIG. 3.

FIG. 6 is a cross-sectional view of FIG. 3, taken along a line VI-VI.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to an electronic module. The electronic module includes a case and a connecting member. The case includes a top panel and a side panel coupled to the top panel and substantially perpendicular to the top panel. The top panel includes two opposite elastic pieces. The connecting member includes a cable extending from the side panel and a connector coupled to the cable. The connector is attached to the top panel, and the two opposite elastic pieces are deformable to engage with the connector to prevent the connector from disengaging from the top panel.

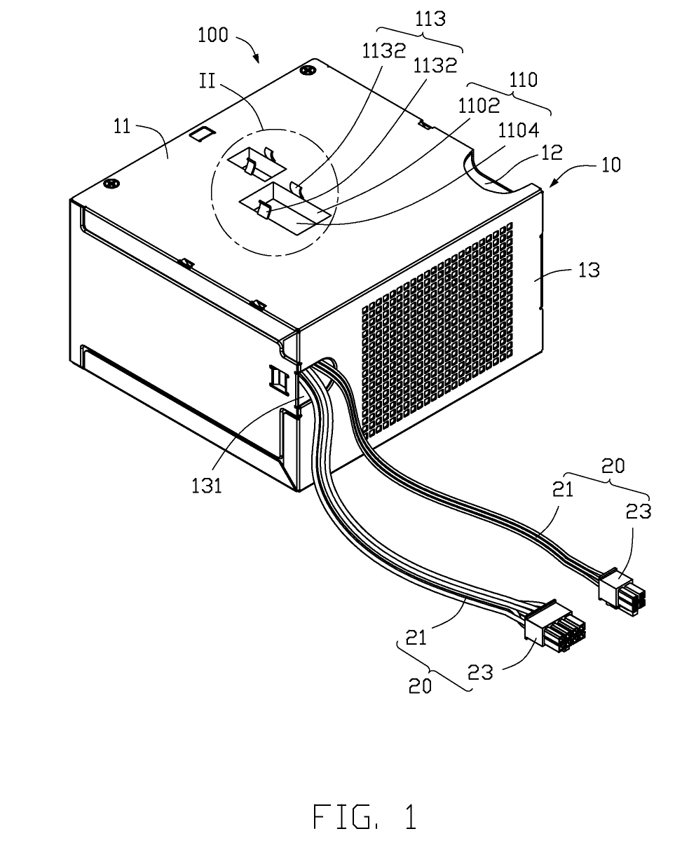

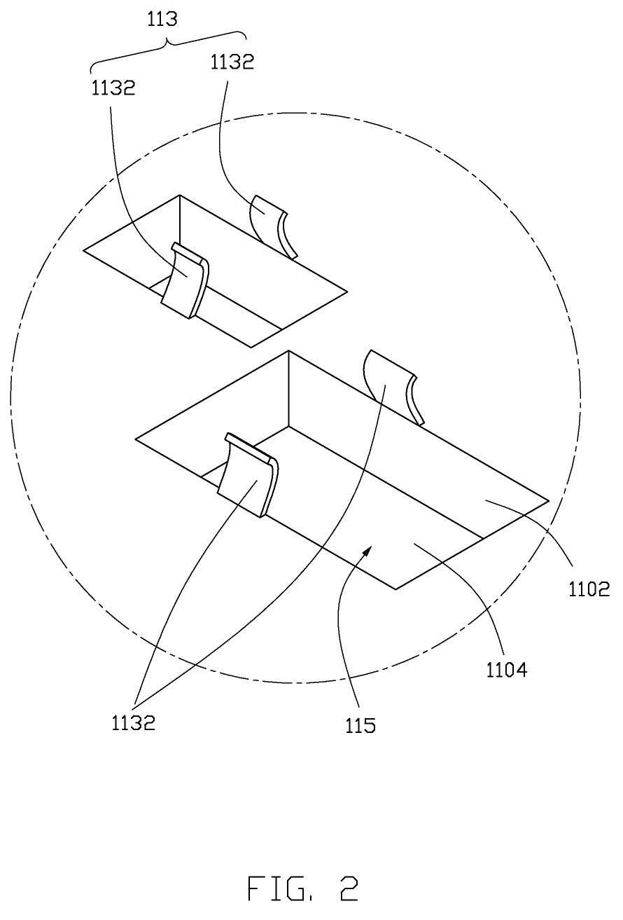

FIGS. 1-2 illustrate an embodiment of an electronic module 100. The electronic module 100 is configured to be received in an electronic device (not shown). In at least one embodiment, the electronic module 100 can be a power supply module, which can be supply power for the electronic device, such as a computer.

The electronic module 100 can include a case 10 and two connecting members 20. The case 10 can define an accommodating space 12 for receiving an electronic component for supplying power, and the electronic component can be connected to the connecting members 20. The case 10 can include a top panel 11, with an inner surface facing the accommodating space 12 and an outer surface opposite the inner surface, and a side panel 13, abutting the top panel 11, with an inner surface facing the accommodating space 12 and an outer surface opposite the inner surface. In at least one embodiment, the top panel 11 is substantially perpendicular to the side panel 13.

The top panel 11 comprises two receiving portions 110 and two clipping devices 113. Each receiving portion 110 and each clipping device 113 corresponds to each connecting member 20. The receiving portion 110 can include a plurality of coupling pieces 1102 and a bottom piece 1104 coupled to the plurality of coupling pieces 1102. In at least one embodiment, the bottom piece 1104 is substantially parallel to the top panel 11 and is substantially perpendicular to each coupling piece 1102, and the plurality of coupling pieces 1102 can includes four coupling pieces 1102 coupled to each other. The four coupling pieces 1102 and the bottom piece 1104 cooperatively define a receiving space 115.

The clipping device 113 can include two opposite elastic pieces 1132. The two elastic pieces 1132 extend from opposite edges of the receiving space 115. In at least one embodiment, each elastic piece 1132 is substantially arcuate.

The side panel 13 defines an opening 131. The two connecting members 20 can extend out of the case 10 via the opening 131.

Each connecting member 20 can include a cable 21 extending out of the opening 131 and a connector 23 coupled to the cable 21. The cable 21 can be bent for allowing the connector 23 to be located on the top panel 11 and can be received in the receiving space 115.

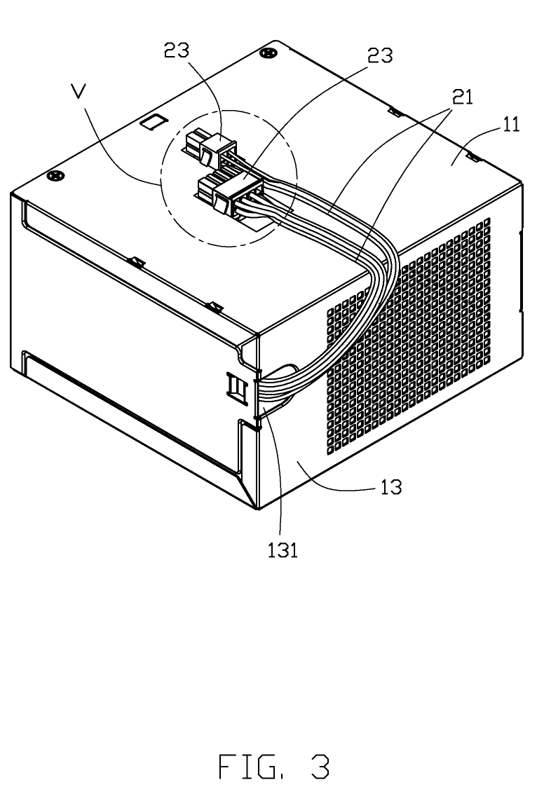

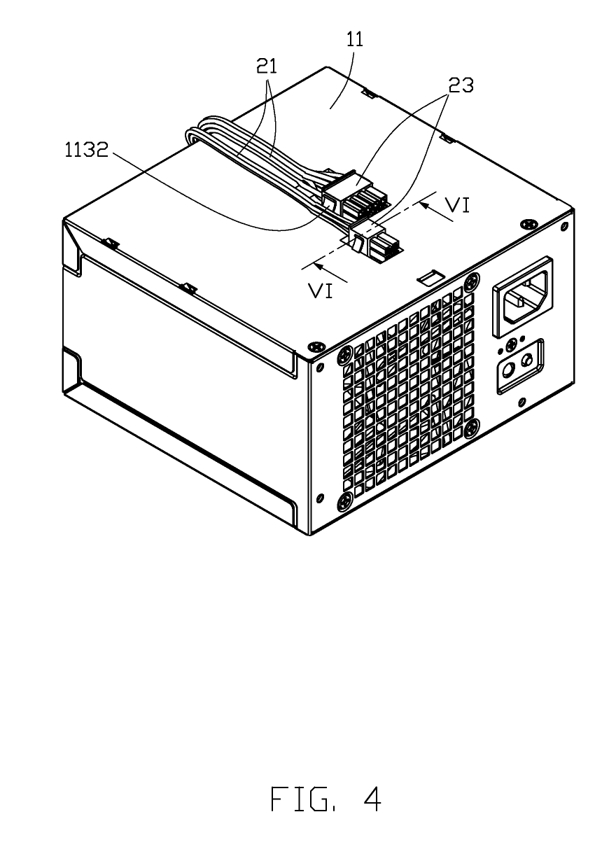

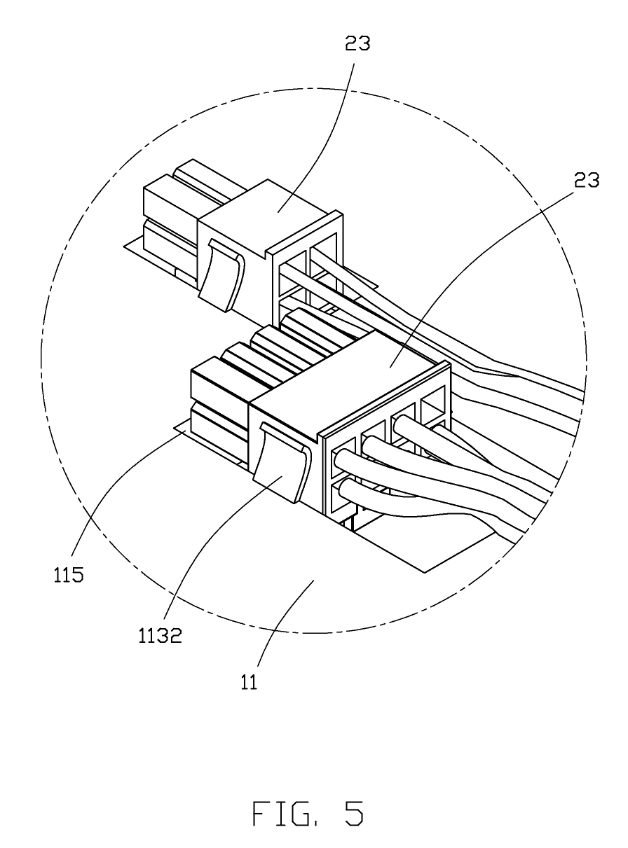

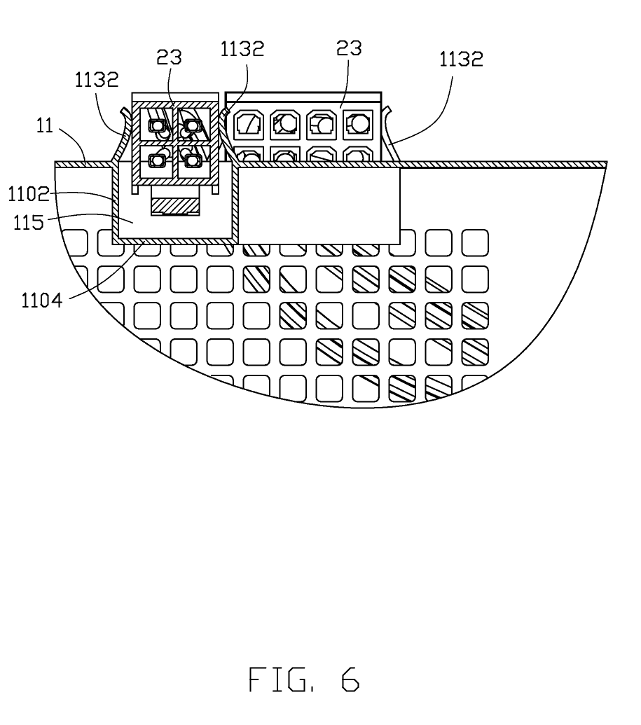

FIGS. 3, 4, 5 and 6 illustrate the electronic module 100. In assembly, the cable 21 is bent for allowing the connector 23 to be located on the top panel 11. The two elastic pieces 1132 are deformed in opposite directions to allow the connector 23 to be received in the receiving space 115. The two elastic pieces 1132 are released to clip to the opposite sides of the connector 23, to prevent the connector 23 from moving out of the receiving space 115. Therefore, the connector 23 can be secured to the top panel 11.

In use, the electronic module 100 is caught by a mechanical arm (not shown) to be connected to another electronic module (not shown), such as a motherboard. Because the connectors 23 are clipped by the elastic pieces 1132, the connector 23 cannot drop, and the electronic module 100 can be easily connected to another electronic module by the mechanical arm. In addition, the cables 21 abut the side panel 13 and can be orderly managed.

The embodiments shown and described above are only examples. Many details are often found in the art such as the other features of a electronic module. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. An electronic module comprising:
a case comprising a top panel and a side panel coupled to the top panel; the top panel comprising a receiving portion and a clipping device; and
a connecting member comprising a cable extending from the side panel and a connector coupled to the cable;
wherein the cable abuts the side panel, and the connector is received in the receiving portion and is clipped to the clipping device.

2. The electronic module of claim 1, wherein the receiving portion defines a receiving space, and the connector is received in the receiving space.

3. The electronic module of claim 2, wherein the receiving portion comprises a plurality of coupling pieces coupled to the top panel and a bottom piece coupled to the plurality of coupling pieces, and the receiving space is defined by the plurality of coupling pieces and the bottom piece.

4. The electronic module of claim 3, wherein the bottom piece is substantially perpendicular to each coupling piece and is substantially parallel to the top panel.

5. The electronic module of claim 3, wherein the clipping device comprises two elastic pieces, and the two elastic pieces extend from opposite coupling pieces.

6. The electronic module of claim 5, wherein each elastic piece is substantially arcuate.

7. The electronic module of claim 1, wherein an opening is defined in the side panel, and the cable extends out of the side panel via the opening.

8. The electronic module of claim 1, wherein the electronic module is a power supply module, and the power supply module is configured to be received in a computer.

9. An electronic device comprising:
a case comprising a top panel and a side panel coupled to the top panel; the side panel substantially perpendicular to the top panel, and the top panel comprising two opposite elastic pieces; and
a connecting member comprising a cable extending from the side panel and a connector coupled to the cable;
wherein the connector is attached to the top panel, and the two opposite elastic pieces is deformable to engage with the connector to prevent the connector from disengaging from the top panel.

10. The electronic module of claim 9, wherein the top panel defines a receiving portion, a receiving space is defined in the receiving portion, and the connector is received in the receiving space.

11. The electronic module of claim 10, wherein the receiving portion comprises a plurality of coupling pieces coupled to the top panel and a bottom piece coupled to the plurality of coupling pieces, and the receiving space is defined by the plurality of coupling pieces and the bottom piece.

12. The electronic module of claim 11, wherein the bottom piece is substantially perpendicular to each coupling piece and is substantially parallel to the top panel.

13. The electronic module of claim 11, wherein the two opposite elastic pieces extend from opposite coupling pieces.

14. The electronic module of claim 9, wherein each elastic piece is substantially arcuate.

15. The electronic module of claim 9, wherein an opening is defined in the side panel, and the cable extends out of the side panel via the opening.

16. The electronic module of claim 9, wherein the electronic module is a power supply module, and the power supply module is configured to be received in a computer.

17. An electronic module comprising:
A case defining an accommodating space for receiving electronic components, the case having a top panel, with an inner surface facing the accommodating space and an outer surface opposite the inner surface, and a side panel, abutting the top panel, with an inner surface facing the accommodating space and an outer surface opposite the inner surface;
a connecting member, the connecting member having:
a connector; and
a cable having a first end connectable to one or more of the received electronic components, and a second end, opposite the first end, connected to the connector; and
wherein, the second end of the cable extends out from the accommodating space, external to the case;
wherein, a receiving space is defined in the outer surface of the top panel;
wherein, a clipping device is positioned substantially near at least one edge of the receiving space;
wherein, at least a portion of the connector is receivable within the receiving space and held substantially in place by the clipping device.
